(19) United States
(12) Patent Application Publication
(10) Pub. No.: US 2025/0295017 A1
(43) Pub. Date: Sep. 18, 2025

(54) DISPLAY MODULE, ELECTRONIC APPARATUS AND METHOD OF MANUFACTURING THE SAME

(71) Applicant: SAMSUNG DISPLAY CO., LTD., YONGIN-SI (KR)

(72) Inventors: YUNG BIN CHUNG, Yongin-si (KR); JINGYU KIM, Yongin-si (KR); JUNGYUN JO, Yongin-si (KR)

(21) Appl. No.: 19/020,124

(22) Filed: Jan. 14, 2025

(30) Foreign Application Priority Data
Mar. 12, 2024 (KR) 10-2024-0034196

(51) Int. Cl. H10K 59/80; H10K 59/12

(52) U.S. Cl. CPC H10K 59/8792; H10K 59/1201

(57) ABSTRACT

A display module including: a display panel; and a light control layer disposed on the display panel, the light control layer including a plurality of light control patterns extending in a first direction and spaced apart from each other in a second direction intersecting the first direction, each of the light control patterns including: a protrusion pattern extending in the first direction and including a first side surface and a second side surface opposite to the first side surface in the second direction; a first light shielding pattern disposed on the first side surface; and a second light shielding pattern disposed on the second side surface, wherein each 10 of the first light shielding pattern and the second light shielding pattern includes amorphous carbon or silicon carbide.

### CROSS-REFERENCE TO RELATED APPLICATION(S)

This application claims priority under 35 U.S.C. § 119 to Korean Patent Application No. 10-2024-0034196, filed on Mar. 12, 2024 in the Korean Intellectual Property Office, the disclosure of which is incorporated by reference herein in its entirety.

### 1. TECHNICAL FIELD

The present disclosure relates to a display module including a light control layer that controls light with an exit angle equal to or greater than a predetermined angle, electronic apparatus, and a method of manufacturing the same.

### 2. DESCRIPTION OF RELATED ART

With the advancement of the information society, the demand for a variety of display devices to display images is increasing. For example, display devices are integrated into various electronic products such as smartphones, digital cameras, notebook computers, navigation units, and smart televisions. In addition, they are used in Center Information Displays (CID) mounted on vehicle instrument panels, such as a center fascia or a dashboard.

A method is needed to control light emitted laterally from the display device to improve its front luminance.

### SUMMARY

The present disclosure provides a display module with a light control layer designed to enhance front luminance and ensure privacy protection.

The present disclosure provides a method of manufacturing the display module with the light control layer designed to enhance front luminance and ensure privacy protection.

An embodiment of the present disclosure provides a display module including: a display panel; and a light control layer disposed on the display panel, the light control layer including a plurality of light control patterns extending in a first direction and spaced apart from each other in a second direction intersecting the first direction, each of the light control patterns including: a protrusion pattern extending in the first direction and including a first side surface and a second side surface opposite to the first side surface in the second direction; a first light shielding pattern disposed on the first side surface; and a second light shielding pattern disposed on the second side surface, wherein each of the first light shielding pattern and the second light shielding pattern includes amorphous carbon or silicon carbide.

Each of the first light shielding pattern and the second light shielding pattern has an extinction coefficient greater than an extinction coefficient of the protrusion pattern.

The extinction coefficient of each of the first light shielding pattern and the second light shielding pattern is equal to or greater than about 0.32 and equal to or smaller than about 0.43.

The light control layer further includes a coating layer disposed on the light control patterns.

Each of the protrusion pattern and the coating layer includes an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The light control layer includes a hole between two adjacent light control patterns, and the coating layer includes: a first portion in the hole; and a second portion disposed on the first portion and the plurality of light control patterns.

The first portion is directly in contact with each of the first light shielding pattern and the second light shielding pattern.

The first light shielding pattern is directly disposed on the first side surface, and the second light shielding pattern is directly disposed on the second side surface.

A width of each of the light control patterns in the second direction is greater than a distance between two adjacent light control patterns in the second direction.

A width of each of the first light shielding pattern and the second light shielding pattern in the second direction is smaller than a width of the protrusion pattern in the second direction.

The width of each of the first light shielding pattern and the second light shielding pattern is equal to or smaller than about 2 micrometers.

A height of each of the first light shielding pattern and the second light shielding pattern is substantially the same as a height of the protrusion pattern.

The display panel includes a plurality of light emitting elements, and each of the plurality of light emitting elements overlaps two or more of the light control patterns when viewed in a plane.

An embodiment of the present disclosure provides a method of manufacturing a display module, including: forming a preliminary first light control layer on a display panel; etching the preliminary first light control layer to form a preliminary second light control layer including a plurality of protrusion patterns extending in a first direction and including a first side surface and a second side surface opposite to the first side surface in a second direction intersecting the first direction and a plurality of preliminary holes between two adjacent protrusion patterns; forming a light shielding layer including a first light shielding pattern portion overlapping each of the plurality of preliminary holes, a second light shielding pattern portion disposed on the plurality of protrusion patterns, a third light shielding pattern portion disposed on the first side surface, and a fourth light shielding pattern portion disposed on the second side surface; and etching the first and second light shielding pattern portions to form a plurality of light control patterns including one of the protrusion patterns, a first light shielding pattern disposed on the first side surface, and a second light shielding pattern disposed on the second side surface, wherein the first light shielding patterns and the second light shielding patterns include amorphous carbon or silicon carbide.

The method further including forming a coating layer including a first portion filled in a hole between two adjacent light control patterns and a second portion disposed on the first portion, the first light shielding patterns, the second light shielding patterns, and the protrusion patterns.

The forming of the light shielding layer includes depositing a light shielding material including amorphous carbon or silicon carbide on the display panel through chemical vapor deposition.

The preliminary first light control layer is formed through inkjet printing.

The first light shielding pattern portion and the second light shielding pattern portion are removed through an anisotropic dry etching process in the forming of the first light shielding pattern and the second light shielding pattern.

Each of the first light shielding pattern and the second light shielding pattern has an extinction coefficient equal to or greater than about 0.32 and equal to or smaller than about 0.43.

Each of the plurality of preliminary holes completely penetrates through the preliminary second light control layer.

As described above, the display module includes the light control layer that absorbs side-emitted light and provides excellent front luminance, thereby enhancing display quality and privacy protection.

The manufacturing method of the display module, which includes forming the light shielding layer, ensures excellent front luminance and improves production yield.

### BRIEF DESCRIPTION OF THE DRAWINGS

The above and other features of the present disclosure will become readily apparent by reference to the following detailed description, considered in conjunction with the accompanying drawings, in which:

FIGS. 1A and 1B are perspective views of a display device according to an embodiment of the present disclosure;

FIG. 2 is an exploded perspective view of a display device according to an embodiment of the present disclosure;

FIG. 3A is a plan view of a display device according to an embodiment of the present disclosure;

FIG. 3B is an enlarged plan view of an area TT′ of FIG. 3A;

FIG. 4 is a cross-sectional view taken along a line I-I′ of FIG. 3A;

FIG. 5 is an enlarged cross-sectional view of an area AA′ of FIG. 4;

FIG. 6 is a flowchart illustrating a method of manufacturing a display module according to an embodiment of the present disclosure; and

FIGS. 7, 8, 9, 10, 11 and 12 are cross-sectional views of a method of manufacturing a display module according to an embodiment of the present disclosure.

### DETAILED DESCRIPTION OF THE EMBODIMENTS

The present disclosure may be modified and implemented in various ways, with specific embodiments illustrated in the drawings and described in detail below. However, the present disclosure is not limited to these particular forms, and should be construed to include all modifications, equivalents, or replacements that align with the spirit and scope of the present disclosure.

In the present disclosure, references to an element (or area, layer, or portion) being “on”, “connected to” or “coupled to” another element or layer mean it can be directly on, connected or coupled to the other element or layer or intervening elements or layers may be present.

Like numerals refer to like elements throughout this disclosure. In the drawings, the thickness, ratios, and dimensions of components are exaggerated to enhance the clarity of the technical content. As used herein, the term “and/or” may include any combination of one or more of the listed items.

It will be understood that, although the terms first, second, etc. may be used herein to describe various elements, these elements should not be limited by these terms. These terms are used to distinguish one element from another element. Thus, a first element discussed below could be referred to as a second element. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein to describe the relative positions of elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by those of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

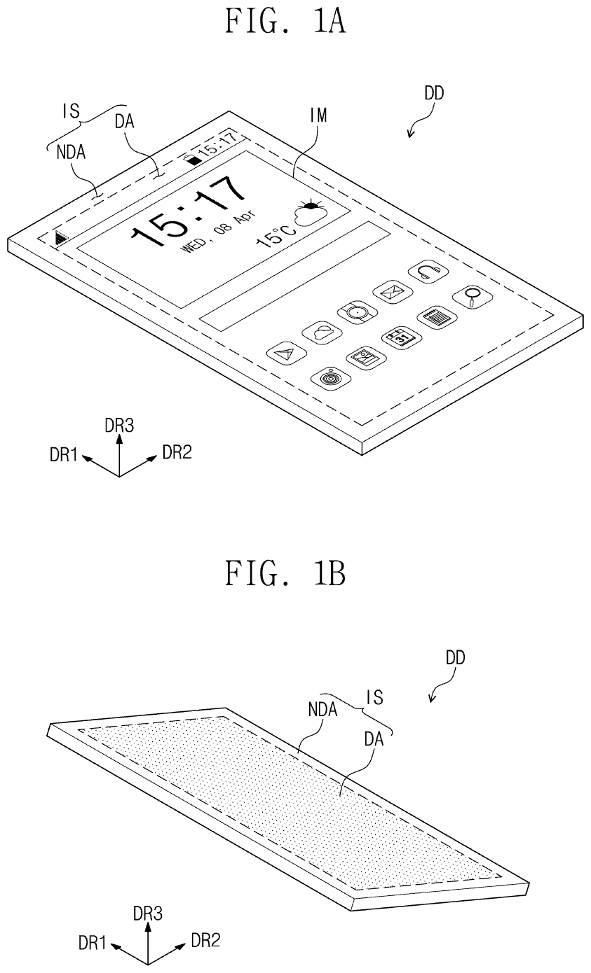

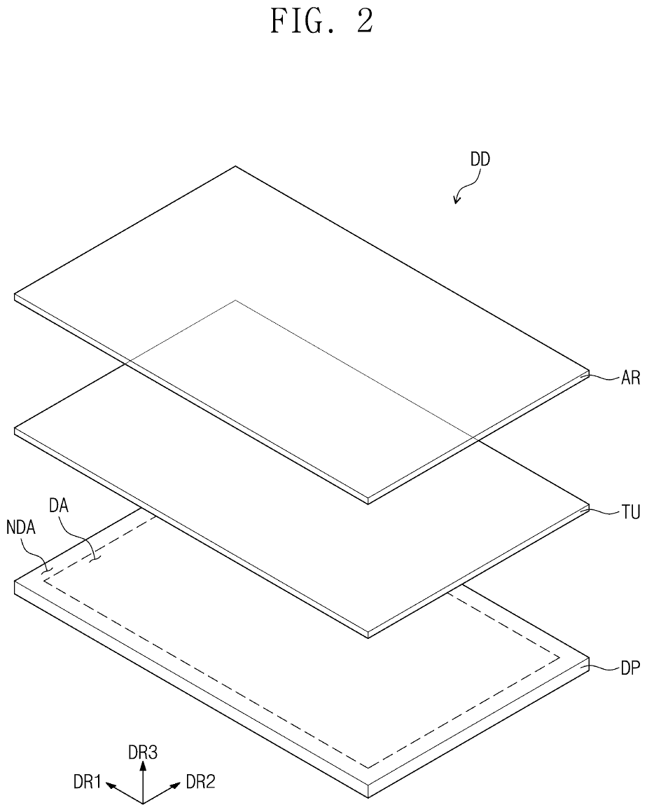

FIGS. 1A and 1B are perspective views of a display device DD according to an embodiment of the present disclosure. FIG. 2 is an exploded perspective view of the display device DD according to an embodiment of the present disclosure. FIG. 1B is a side perspective view of the display device shown in FIG. 1A shown from a different angle.

FIG. 1A shows a portable electronic device as a representative example of the display device DD, however, the present disclosure should not be limited thereto or thereby. The display device DD may be applied to a large-sized electronic item, such as a television set, a monitor, or an outdoor billboard, and a small- and medium-sized electronic item, such as a personal computer, a notebook computer, a personal digital assistant, a car navigation unit, a game unit, a smartphone, a tablet computer, and a camera. However, these are merely examples, and the display device DD may be applied to other electronic devices as long as they do not depart from the concept of the present disclosure

The display device DD may have a cuboidal shape having a thickness in a third direction DR3 on a plane defined by a first direction DR1 and a second direction DR2 crossing the first direction DR1. However, this is merely an example, and the display device DD may have a variety of shapes.

According to an embodiment, upper (or front) and lower (or rear) surfaces of each member may be described with respect to a direction in which an image IM is displayed. The front and rear surfaces may be opposite to each other in the third direction DR3, and a normal line direction of each of the upper and lower surfaces may be substantially parallel to the third direction DR3.

The first, second, and third directions DR1, DR2, and DR3 are relative to one another and may be adjusted or reoriented as needed.

The display device DD may display the image IM through a display surface IS. The display surface IS may include a display area DA in which the image IM is displayed and a non-display area NDA adjacent to the display area DA. The image IM is not displayed through the non-display area NDA. The image IM may include a video or a still image. FIG. 1A shows a plurality of application icons and a clock widget as representative examples of the image IM.

The display area DA may have a quadrangular shape. The non-display area NDA may surround the display area DA. However, they should not be limited to these configurations, and the shapes of the display area DA and the non-display area NDA may be designed in relation to one another. In addition, the non-display area NDA may not exist on a front surface of the display device DD.

The display device DD may be flexible. The term “flexible” used herein refers to the ability to bend. A flexible display device may include all structures, ranging from those that can be fully bent to those bent at the scale of a few nanometers. For example, the display device DD may be a curved display device or a foldable display device, however, it should not be limited thereto or thereby. According to an embodiment, the display device DD may be rigid.

Referring to FIGS. 1A and 1B, a luminance rate of the display device DD may be changed depending on a user's gaze. In other words, the luminance of the display device DD may adjust based on the user's gaze. When a user is looking at the display area DA of the display device DD in front of the display device DD, the luminance rate of the display device DD, which is perceived by the user, may be maximized. On the other hand, when the user is looking at the display area DA of the display device DD at a side of the display device DD, i.e., when an angle (referred to as a “viewing angle”) between the user's gaze and the display area DA is smaller than about 90 degrees, the perceived luminance rate of the display device DD may be reduced. As an example, when the viewing angle is equal to or smaller than about 45 degrees, the luminance rate of the display device DD decreases to less than about 1% compared its luminance rate at an angle of about 90 degrees, making the image IM unrecognizable to the user as shown in FIG. 1B.

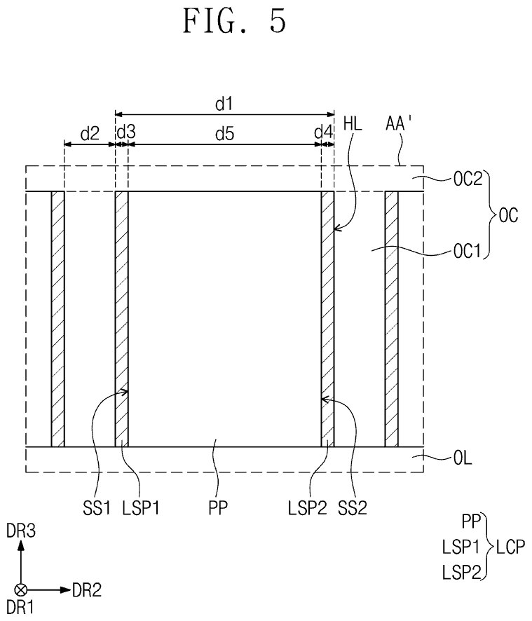

According to the present disclosure, the display device DD includes a plurality of light control patterns LCP (refer to FIG. 5), which enhance a rate (referred to as a “front luminance rate”) of light traveling in the third direction DR3 with respect to the total amount of light emitted by the display device DD.

FIG. 2 is an exploded perspective view of the display device DD according to an embodiment of the present disclosure. Referring to FIG. 2, the display device DD may include a display panel DP, a sensor layer TU, and a light control layer AR, which are sequentially stacked in the third direction DR3.

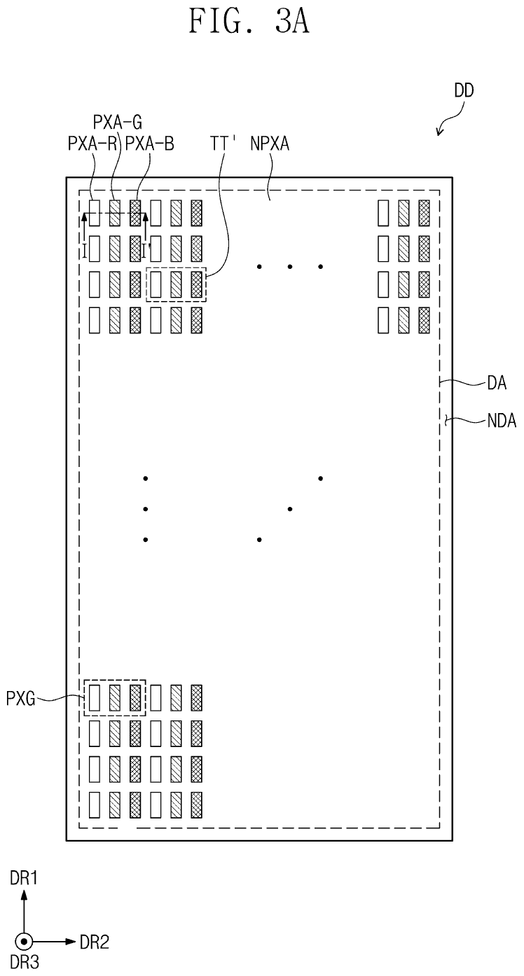

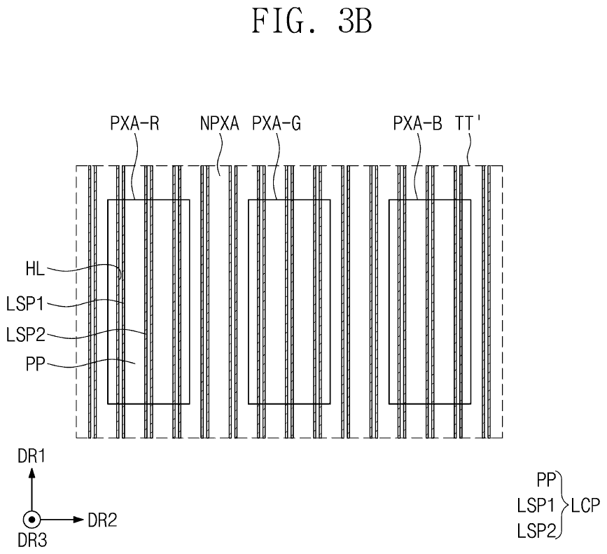

The display panel DP may include a plurality of pixels in an area corresponding to the display area DA. The pixels may correspond to a plurality of pixel areas PXA-R, PXA-B, and PXA-G (refer to FIG. 3A). The pixels may generate lights in response to electrical signals. The display area DA may display the image IM corresponding to the lights generated by the pixels.

According to an embodiment, the display panel DP may be a self-luminous display panel. As an example, the display panel DP may be a micro-light emitting diode (LED) display panel, a nano-LED display panel, an organic light emitting display panel, or a quantum dot light emitting display panel. However, this is merely an example. The display panel DP should not be limited thereto or thereby as long as the display panel DP is the self-luminous display panel.

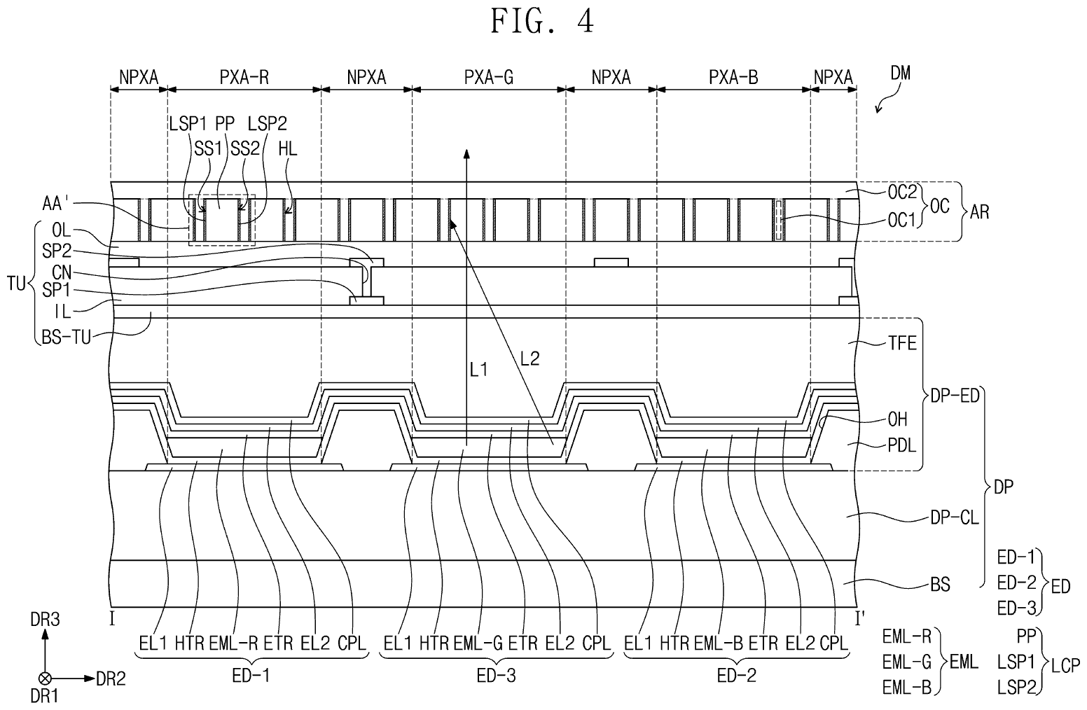

A light emitting layer of the organic light emitting display panel may include an organic light emitting material. A light emitting layer of the quantum dot light emitting display panel may include a quantum dot and/or a quantum rod. The micro-LED display panel may include a micro light-emitting diode element that is a micro light-emitting element, and the nano-LED display panel may include a nano light-emitting diode element. Hereinafter, the organic light emitting display panel will be described as the display panel DP. The components of the display panel DP will be described in detail with reference to FIGS. 3A to 4.

The light control layer AR may be disposed on the display panel DP. The light control layer AR may absorb a light traveling to a side surface of the display device DD and may increase the front luminance rate. The structures and functions of the light control layer AR will be described in detail with reference to FIGS. 3B and 4.

The sensor layer TU may be disposed between the display panel DP and the light control layer AR. The sensor layer TU may obtain information required to generate the image IM in the display panel DP in response to an external input applied thereto. The external input may be a user input. The user input may include various forms of external inputs, such as a part of a user's body, light, heat, pen, or pressure.

FIG. 3A is a plan view of the display device DD according to an embodiment of the present disclosure. FIG. 3B is an enlarged plan view of an area TT′ of FIG. 3A. FIG. 4 is a cross-sectional view taken along a line I-I′ of FIG. 3A. FIG. 5 is an enlarged cross-sectional view of an area AA′ of FIG. 4.

Referring to FIGS. 3A and 4, the display device DD may include a display module DM. In the present disclosure, the display device DD may have substantially the same configuration as the display module DM. The display module DM may include the display panel DP and the light control layer AR. The display module DM may further include the sensor layer TU. As the display module DM includes both the display panel DP and the sensor layer TU, the display module DM may sense the external input while displaying the image IM (refer to FIG. 1A).

The display panel DP may include a base substrate BS, a circuit layer DP-CL, and a display element layer DP-ED, which are sequentially stacked. The display element layer DP-ED may include a pixel definition layer PDL, light emitting elements ED disposed in pixel openings OH formed in the pixel definition layer PDL, and an encapsulation layer TFE disposed on the light emitting elements ED.

The base substrate BS may be rigid or flexible. The base substrate BS may be a polymer substrate, a plastic substrate, a glass substrate, a metal substrate, or a composite material substrate. The base substrate BS may have a single-layer or multi-layer structure. The base substrate BS may include a synthetic resin film, and the base substrate BS may have a multi-layer structure of multiple synthetic resin films. The synthetic resin film may include a polyimide-based resin, an acrylic-based resin, a vinyl-based resin, an epoxy-based resin, a urethane-based resin, a cellulose-based resin, and a perylene-based resin, however, a material for the synthetic resin film should not be limited thereto or thereby.

The circuit layer DP-CL may be disposed on the base substrate BS. The circuit layer DP-CL may include an insulating layer, a semiconductor pattern, a conductive pattern, and a signal line. The circuit layer DP-CL may include a plurality of transistors formed by the semiconductor pattern, the conductive pattern, and the signal line. Each of the transistors may include a control electrode, an input electrode, and an output electrode. For example, the circuit layer DP-CL may include a switching transistor and a driving transistor to drive the light emitting element ED.

The display element layer DP-ED may be disposed on the circuit layer DP-CL. The display element layer DP-ED may include the pixel definition layer PDL, the light emitting element ED, and the encapsulation layer TFE.

The light emitting element ED may include a plurality of light emitting elements ED-1, ED-2, and ED-3. Each of the light emitting elements ED-1, ED-2, and ED-3 may include a first electrode EL1, a hole transport region HTR, a corresponding one of light emitting layers EML-R, EML-B, and EML-G, an electron transport region ETR, a second electrode EL2, and a capping layer CPL. A first light emitting element ED-1 may include a first light emitting layer EML-R overlapping a first pixel area PXA-R. A second light emitting element ED-2 may include a second light emitting layer EML-B overlapping a second pixel area PXA-B. A third light emitting element ED-3 may include a third light emitting layer EML-G overlapping a third pixel area PXA-G.

The pixel definition layer PDL may be disposed on the circuit layer DP-CL. The pixel definition layer PDL may include the pixel openings OH formed within it. The pixel openings OH may correspond to the pixel areas PXA-R, PXA-B, and PXA-G, respectively. A light shielding area NPXA may be defined between the pixel areas PXA-R, PXA-B, and PXA-G adjacent to each other and may correspond to the pixel definition layer PDL.

The pixel definition layer PDL may have a light absorbing property. For example, the pixel definition layer PDL may have a black color. The pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light shielding pattern having a light shielding property.

The pixel definition layer PDL may include an organic resin or an inorganic material. As an example, the pixel definition layer PDL may include a polyacrylate-based resin, a polyimide-based resin, silicon nitride (SiNₓ), silicon oxide (SiOₓ), or silicon oxynitride (SiOₓN_{y}).

FIG. 4 shows a structure in which the light emitting layers EML-R, EML-B, and EML-G of the light emitting elements ED-1, ED-2, and ED-3 are disposed in the pixel openings OH formed in the pixel definition layer PDL. Additionally, the hole transport region HTR, the electron transport region ETR, the second electrode EL2, and the capping layer CPL are commonly disposed in the light emitting elements ED-1, ED-2, and ED-3. However, the present disclosure should not be limited thereto or thereby. Different from the structure shown in FIG. 4, the hole transport region HTR, the electron transport region ETR, the second electrode EL2, and the capping layer CPL may be disposed in the pixel openings OH formed in the pixel definition layer PDL after being patterned. As an example, according to an embodiment, at least one of the hole transport region HTR, the light emitting layers EML-R, EML-B, and EML-G, the electron transport region ETR, the second electrode EL2, and the capping layer CPL of the light emitting elements ED-1, ED-2, and ED-3 may be patterned by an inkjet printing method.

In the light emitting element ED, the first electrode EL1 may be disposed on the circuit layer DP-CL. The first electrode EL1 may be an anode or a cathode. In addition, the first electrode EL1 may be a pixel electrode. The first electrode EL1 may be a transmissive electrode, a transflective electrode, or a reflective electrode.

The hole transport region HTR may be disposed between the first electrode EL1 and the light emitting layer EML. The hole transport region HTR may include at least one of a hole injection layer, a hole transport layer, and an electron block layer. The hole transport region HTR may be commonly disposed to overlap the pixel areas PXA-R, PXA-B, and PXA-G and the pixel definition layer PDL disposed between the pixel areas PXA-R, PXA-B, and PXA-G to distinguish the pixel areas PXA-R, PXA-B, and PXA-G from each other, however, the present disclosure should not be limited thereto or thereby. According to an embodiment, the hole transport region HTR may be patterned into a plurality of portions to be respectively disposed in the pixel areas PXA-R, PXA-B, and PXA-G.

The light emitting layer EML may be disposed on the first electrode EL1. The light emitting layer EML may include the light emitting layers EML-R, EML-B, and EML-G. The first light emitting layer EML-R may overlap the first pixel area PXA-R and may emit a first light. The second light emitting layer EML-B may overlap the second pixel area PXA-B and may emit a second light. The third light emitting layer EML-G may overlap the third pixel area PXA-G and may emit a third light. The first, second, and third lights respectively emitted from the light emitting elements ED-1, ED-2, and ED-3 may have different wavelength ranges from each other. As an example, the first light may be a red light within a wavelength range equal to or greater than about 625 nm and equal to or smaller than about 675 nm. As an example, the second light may be a blue light within a wavelength range equal to or greater than about 410 nm and equal to or smaller than about 480 nm. As an example, the third light may be a green light within a wavelength range equal to or greater than about 500 nm and equal to or smaller than about 570 nm.

The electron transport region ETR may be disposed between the light emitting layer EML and the second electrode EL2. The electron transport region ETR may include at least one of an electron injection layer, an electron transport layer, and a hole block layer. The electron transport region ETR may be commonly disposed to overlap the pixel areas PXA-R, PXA-B, and PXA-G and the pixel definition layer PDL disposed between the pixel areas PXA-R, PXA-B, and PXA-G to distinguish the pixel areas PXA-R, PXA-B, and PXA-G from each other, however, the present disclosure should not be limited thereto or thereby. According to an embodiment, the electron transport region ETR may be patterned into a plurality of portions to be respectively disposed in the pixel areas PXA-R, PXA-B, and PXA-G.

The second electrode EL2 may be disposed on the electron transport region ETR. The second electrode EL2 may be a common electrode. The second electrode EL2 may be a cathode or an anode, however, the present disclosure should not be limited thereto or thereby. As an example, when the first electrode EL1 is the anode, the second electrode EL2 may be the cathode, and when the first electrode EL1 is the cathode, the second electrode EL2 may be the anode. The second electrode EL2 may be a transmissive electrode, a transflective electrode, or a reflective electrode.

The capping layer CPL may be further disposed on the second electrode EL2. The capping layer CPL may have a single-layer or multi-layer structure. According to an embodiment, the capping layer CPL may be an organic layer or an inorganic layer. As an example, when the capping layer CPL includes an inorganic material, the inorganic material may include SiON, SiNx, SiOy, an alkali metal compound, such as LiF, an alkaline earth metal compound, such as MgF2, or the like. As an example, when the capping layer CPL includes an organic material, the organic material may include α-NPD, NPB, TPD, m-MTDATA, Alq₃, CuPc, TPD15(N4,N4,N4′,N4′-tetra (biphenyl-4-yl) biphenyl-4,4′-diamine), TCTA(4,4′,4″-Tris (carbazol-9-yl)triphenylamine), or the like or may include an epoxy resin or an acrylate, such as methacrylate, however, it should not be limited thereto or thereby.

The capping layer CPL may have a refractive index equal to or greater than about 1.6. In detail, the refractive index of the capping layer CPL may be equal or greater than about 1.6 with respect to the light having the wavelength range equal to or greater than about 550 nm and equal to or smaller than about 660 nm.

The encapsulation layer TFE may be disposed on the pixel definition layer PDL and may cover the light emitting element ED. The encapsulation layer TFE may be disposed on the capping layer CPL and may fill a portion of the pixel opening OH. The encapsulation layer TFE may protect the light emitting element ED from moisture and oxygen, and the encapsulation layer TFE may protect the light emitting element ED from a foreign substance, such as dust particles.

FIG. 4 shows the encapsulation layer TFE as a single layer, however, the encapsulation layer TFE may include at least one organic layer, at least one inorganic layer, or both the organic and inorganic layers. The encapsulation layer TFE may have a thin film encapsulation layer structure including at least one organic layer and at least one inorganic layer. As an example, the encapsulation layer TFE may have a structure where the organic and inorganic layers are alternately stacked, or where an inorganic layer, an organic layer, and another inorganic layer are sequentially stacked.

The inorganic layer included in the encapsulation layer TFE may include a silicon nitride layer, a silicon oxynitride layer, a silicon oxide layer, a titanium oxide layer, or an aluminum oxide layer, however, it should not be limited thereto. The organic layer included in the encapsulation layer TFE may include an acrylic-based organic layer, however, it should not be limited thereto.

The sensor layer TU may be disposed between the display panel DP and the light control layer AR in the display module DM. The sensor layer TU may obtain information required to generate images in the display panel DP in response to an external input applied thereto. The external input may be a user input. The user input may include various forms of external inputs, such as a part of a user's body, light, heat, pen, or pressure.

The sensor layer TU may include a sensor base substrate BS-TU, a first conductive layer SP1, an inorganic insulating layer IL, a second conductive layer SP2, and an organic insulating layer OL. The first conductive layer SP1 may be disposed on the sensor base substrate BS-TU. The inorganic insulating layer IL may cover the first conductive layer SP1 and may be disposed on the sensor base substrate BS-TU and the first conductive layer SP1. The second conductive layer SP2 may be disposed on the inorganic insulating layer IL. The organic insulating layer OL may cover the second conductive layer SP2 and may be disposed on the inorganic insulating layer IL and the second conductive layer SP2.

The sensor base substrate BS-TU may be an inorganic layer containing one of silicon nitride, silicon oxynitride, and silicon oxide. According to an embodiment, the sensor base substrate BS-TU may be an organic layer containing an epoxy resin, an acrylic resin, or an imide-based resin. The sensor base substrate BS-TU may have a single-layer structure or a multi-layer structure of layers stacked in the third direction DR3. The sensor base substrate BS-TU may be disposed directly on the encapsulation layer TFE.

Each of the first conductive layer SP1 and the second conductive layer SP2 may have a single-layer structure or a multi-layer structure of layers stacked in the third direction DR3. The first and second conductive layers SP1 and SP2 having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer (e.g., PEDOT), a metal nanowire, and a graphene.

The first and second conductive layers SP1 and SP2 having the multi-layer structure may include a plurality of metal layers. The metal layers may have a three-layer structure of titanium (Ti)/aluminum (Al)/titanium (Ti). The first and second conductive layers SP1 and SP2 having the multi-layer structure may include at least one metal layer and at least one transparent conductive layer.

The inorganic insulating layer IL may include at least one of aluminum oxide, titanium oxide, silicon oxide, silicon oxynitride, zirconium oxide, and hafnium oxide.

The inorganic insulating layer IL may include a contact hole CN formed within it. The first conductive layer SP1 and the second conductive layer SP2 may be electrically connected to each other through the contact hole CN. The contact hole CN may be filled with a material for the second conductive layer SP2. In other words, the contact hole CN may be filled with material from the second conductive layer SP2.

The organic insulating layer OL may cover the inorganic insulating layer IL and the second conductive layer SP2. The organic insulating layer OL may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The display device DD may include the light shielding area NPXA and the pixel areas PXA-R, PXA-B, and PXA-G. Each pixel area PXA-R, PXA-B, and PXA-G corresponds to the area where light from its respective light emitting element ED-1, ED-2, and ED-3 is emitted. The pixel areas PXA-R, PXA-B, and PXA-G may be spaced apart from each other when viewed in a plane.

Each of the pixel areas PXA-R, PXA-B, and PXA-G may be defined by the pixel definition layer PDL. The light shielding area NPXA may correspond to an area between the pixel areas PXA-R, PXA-B, and PXA-G adjacent to each other and may correspond to the pixel definition layer PDL. Each of the pixel areas PXA-R, PXA-B, and PXA-G may correspond to the pixel. The pixel definition layer PDL may distinguish the light emitting elements ED-1, ED-2, and ED-3 from each other. The light emitting layers EML-R, EML-B, and EML-G of the light emitting elements ED-1, ED-2, and ED-3 may be disposed in the openings OH in the pixel definition layer PDL to be distinguished from each other.

The pixel areas PXA-R, PXA-B, and PXA-G may be grouped into a plurality of groups based on the colors of the light emitted by the corresponding light emitting elements ED-1, ED-2, and ED-3. The display device DD shown in FIGS. 3A and 4 includes three pixel areas PXA-R, PXA-B, and PXA-G respectively emitting red, blue, and green lights. As an example, the display device DD may include the first pixel area PXA-R, the second pixel area PXA-B, and the third pixel area PXA-G, which are distinguished from each other. According to an embodiment, the first pixel area PXA-R may be referred to as a red pixel area, the second pixel area PXA-B may be referred to as a blue pixel area, and the third pixel area PXA-G may be referred to as a green pixel area. In the display device DD, a group including one first pixel area PXA-R, one second pixel area PXA-B, and one third pixel area PXA-G may be referred to as a unit pixel group PXG. According to an embodiment, at least one of the first pixel area PXA-R, the second pixel area PXA-B, and the third pixel area PXA-G included in the unit pixel group PXG may be provided in plural. As an example, the unit pixel group PXG may include two third pixel areas PXA-G, one first pixel area PXA-R, and one second pixel area PXA-B.

According to an embodiment, the light emitting elements ED-1, ED-2, and ED-3 of the display device DD may emit lights having different wavelength ranges from each other. As an example, the display device DD may include the first light emitting element ED-1 emitting the red light, the second light emitting element ED-2 emitting the blue light, and the third light emitting element ED-3 emitting the green light. In other words, the red pixel area PXA-R, the blue pixel area PXA-B, and the green pixel area PXA-G of the display device DD may correspond to the first light emitting element ED-1, the second light emitting element ED-2, and the third light emitting element ED-3, respectively.

However, the present disclosure should not be limited thereto or thereby, and the first, second, and third light emitting elements ED-1, ED-2, and ED-3 may emit the lights having the same wavelength range as each other, or at least one of the first, second, and third light emitting elements ED-1, ED-2, and ED-3 may emit the light having a wavelength range different from the other. As an example, all the first, second, and third light emitting elements ED-1, ED-2, and ED-3 may emit the blue light.

According to an embodiment, the pixel areas PXA-R, PXA-B, and PXA-G of the display device DD may be arranged in a stripe form. In other words, the pixel areas PXA-R, PXA-B, and PXA-G of the display device DD may be arranged in a stripe pattern. Referring to FIG. 3A, each of a plurality of red pixel areas PXA-R, a plurality of blue pixel areas PXA-B, and a plurality of green pixel areas PXA-G may be arranged in the second direction DR2. In addition, the pixel areas may be sequentially arranged in order of the red pixel area PXA-R, the green pixel area PXA-G, and the blue pixel area PXA-B, repeating this pattern.

In FIGS. 3A and 4, the pixel areas PXA-R, PXA-B, and PXA-G are shown to be similar in size, however, they should not be limited thereto or thereby. According to an embodiment, the sizes of the pixel areas PXA-R, PXA-B, and PXA-G may be different from each other depending on the wavelength ranges of the lights emitted therefrom. According to an embodiment, the size of the green pixel area PXA-G may be smaller than the size of the blue pixel area PXA-B. The sizes of the pixel areas PXA-R, PXA-B, and PXA-G refer to their dimensions as viewed in the plane defined by the first direction DR1 and the second direction DR2.

The arrangement of the pixel areas PXA-R, PXA-B, and PXA-G should not be limited to that shown in FIG. 3A. The sequence in which the red pixel area PXA-R, the blue pixel area PXA-B, and the green pixel area PXA-G are arranged can vary based on the display quality requirements of the display device DD. As an example, the pixel areas PXA-R, PXA-B, and PXA-G may be arranged in a PenTile™ matrix or a Diamond Pixel™ matrix.

Referring to FIGS. 3B and 4, the light control layer AR may include the light control patterns LCP. Each of the light emitting elements ED-1, ED-2, and ED-3 may overlap two or more light control patterns LCP among the light control patterns LCP when viewed in the plane. The light shielding area NPXA may overlap one or more light control patterns LCP when viewed in the plane.

FIGS. 3B and 4 show the structure where each of the light emitting elements ED-1, ED-2, and ED-3 overlaps three first light shielding patterns LSP1 and three second light shielding patterns LSP2 when viewed in the plane. Additionally, the light shielding areas NPXA disposed between the first and second light emitting elements ED-1 and ED-2 and between the second and third light emitting elements ED-2 and ED-3 overlap two first light shielding patterns LSP1 and two second light shielding patterns LSP2 when viewed in the plane. However, different from the above, the number of the first light shielding patterns LSP1 and second light shielding patterns LSP2 overlapping the light emitting elements ED-1, ED-2, and ED-3 and the light shielding area NPXA in the plane view may vary.

For the first light emitting elements ED-1, the number of the first light shielding patterns LSP1 overlapping each first light emitting element ED-1 in the plane view may vary. Similarly, for the first light emitting elements ED-1, the number of the second light shielding patterns LSP2 overlapping each first light emitting element ED-1 in the plane view may vary.

For the second light emitting elements ED-2, the number of the first light shielding patterns LSP1 overlapping each second light emitting element ED-2 in the plane view may vary. Similarly, for the second light emitting elements ED-2, the number of the second light shielding patterns LSP2 overlapping each second light emitting element ED-2 in the plane view may vary.

For the third light emitting elements ED-3, the number of the first light shielding patterns LSP1 overlapping each third light emitting element ED-3 in the plane view may vary. Similarly, for the third light emitting elements ED-3, the number of the second light shielding pattern LSP2 overlapping each third light emitting element ED-3 in the plane view may vary.

The number of the first light shielding patterns LSP1 that overlaps the first light emitting element ED-1 when viewed in the plane may be different from the number of the second light shielding patterns LSP2 that overlaps the first light emitting element ED-1 when viewed in the plane. The number of the first light shielding patterns LSP1 that overlaps the second light emitting element ED-2 may be different from the number of the second light shielding patterns LSP2 that overlaps the second light emitting element ED-2 when viewed in the plane. The number of the first light shielding patterns LSP1 that overlaps the third light emitting element ED-3 when viewed in the plane may be different from the number of the second light shielding patterns LSP2 that overlaps the third light emitting element ED-3 when viewed in the plane. The number of the first light shielding patterns LSP1 overlapping the first light emitting element ED-1, the second light emitting element ED-2, and the third light emitting element ED-3 when viewed in the plane may be different from each other. The number of the second light shielding patterns LSP2 overlapping the first light emitting element ED-1, the second light emitting element ED-2, and the third light emitting element ED-3 when viewed in the plane may be different from each other.

Each of the light control patterns LCP may include a protrusion pattern PP, the first light shielding pattern LSP1, and the second light shielding pattern LSP2. The light control patterns LCP may extend in the first direction DR1 and may be arranged in the second direction DR2. The light control pattern LCP may be disposed on the display panel DP. The light control pattern LCP may be disposed on the sensor layer TU. The light control pattern LCP may be disposed on the organic insulating layer OL. The light control pattern LCP may be disposed directly on the organic insulating layer OL. The display module DM may further include a transparent organic layer disposed between the sensor layer TU and the light control layer AR. The transparent organic layer may include a transparent organic material and may transmit the light provided from the display panel DP. The transparent organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The protrusion pattern PP may include a first side surface SS1 and a second side surface SS2 opposite to the first side surface SS1 in the second direction DR2. Each of the first side surface SS1 and the second side surface SS2 may extend in the first direction DR1. The second side surface SS2 may be opposite to the first side surface SS1 in the second direction DR2. The protrusion pattern PP may extend in the first direction DR1. The protrusion pattern PP may include a transparent organic material. The protrusion pattern PP may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin. As an example, the protrusion pattern PP may include the acrylic-based resin.

The first light shielding pattern LSP1 may be disposed on the first side surface SS1. The second light shielding pattern LSP2 may be disposed on the second side surface SS2. The first light shielding pattern LSP1 may be disposed directly on the first side surface SS1. The second light shielding pattern LSP2 may be disposed directly on the second side surface SS2. Each of the first light shielding pattern LSP1 and the second light shielding pattern LSP2 may include at least one of amorphous carbon and silicon carbide (SiC). As an example, the first light shielding pattern LSP1 may include silicon carbide, and the second light shielding pattern LSP2 may include amorphous carbon.

The amorphous carbon of the first light shielding pattern LSP1 or the second light shielding pattern LSP2 may have a refractive coefficient (n) equal to or greater than about 1.873 and an extinction coefficient (k) equal to or greater than about 0.32. The silicon carbide of the first light shielding pattern LSP1 or the second light shielding pattern LSP2 may have a refractive coefficient (n) equal to or greater than about 2.331 and equal to or smaller than about 2.405 and an extinction coefficient (k) equal to or greater than about 0.40 and equal to or smaller than about 0.43. In the present disclosure, the refractive coefficient (n) is a value obtained by dividing the speed of light in a vacuum by the speed of light in a medium, and this value is greater than about 1. The closer the refractive coefficient (n) is to 1, the faster light travels and the less it refracts within the medium compared to when it has a larger value.

The extinction coefficient (referred to as “k”) represents the extent to which light intensity decreases as it passes through a medium. It is obtained by dividing −log(lₜ/l₀) by the product of C and d, where l₀ is the initial light intensity, lₜ is the light intensity after passing through the medium, C is the concentration of the light-absorbing material, and d is the thickness of the medium. A higher k value indicates greater light absorption by the medium, while a lower k suggests increased light reflection by the medium.

A light absorbing material included in a conventional light control layer has a k value of about 0.2. Due to the small k value, a light traveling to a side surface among lights generated in a conventional display panel to which the convention light control layer is applied is not absorbed by the light absorbing material (e.g., a light shielding material) and is reflected. As a result, a side light is generated and the side light is perceived at the side surface. When the side light generated in the display panel is perceived by someone other than the user, privacy protection may be vulnerable.

The k value of the amorphous carbon and the silicon carbide of the first light shielding pattern LSP1 and the second light shielding pattern LSP2 according to the present disclosure may be equal to or greater than about 0.32 and equal to or smaller than about 0.43. The k value of the first light shielding pattern LSP1 and the second light shielding pattern LSP2 may be greater than a k value of the protrusion pattern PP. Since the k value of the amorphous carbon and the silicon carbide of the first light shielding pattern LSP1 and the second light shielding pattern LSP2 of the display module DM is equal to or greater than about 0.32 and equal to or smaller than about 0.43, a light (referred to as a “side light”) L2 traveling to the side surface of the display panel DP among lights L1 and L2 may be absorbed by the first light shielding pattern LSP1 without being reflected. In a case where the side light L2 is reflected without being absorbed by the first light shielding pattern LSP1, the side light L2 may be absorbed by the second light shielding pattern LSP2.

The display module DM according to the present disclosure includes plural first light shielding patterns LSP1 and plural second light shielding patterns LSP2 with high k values, enhancing the absorption of side light L2. As a result, the proportion of front light L1 perceived by the user increases, while the visibility of the side light L2 to others decreases, thereby improving privacy protection.

The light control layer AR may include a hole HL formed between two adjacent light control patterns LCP. The hole HL may be a space between two adjacent light control patterns LCP. A width in the second direction DR2 of the hole HL may be equal to or greater than about 2 micrometers and equal to or smaller than about 4 micrometers. If the width in the second direction DR2 of the hole HL is excessively small, it becomes challenging to deposit the first light shielding pattern LSP1 and the second light shielding pattern LSP2 during a manufacturing process of the display module DM. Conversely, if the width in the second direction DR2 of the hole HL is excessively large, the protrusion pattern PP becomes narrower in the second direction DR2, potentially causing the protrusion pattern PP to shift downward in the second direction DR2 or in the opposite direction.

The light control layer AR may further include a coating layer OC, and at least a portion of the coating layer OC may be disposed on the light control patterns LCP. The coating layer OC may include a first portion OC1 filled in at least a portion of the hole HL and a second portion OC2 disposed on the first portion OC1 and the light control patterns LCP. The coating layer OC may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin. As an example, the coating layer OC may include the methacrylic-based resin. The first portion OC1 and the second portion OC2 may be provided integrally with each other. The hole HL may be completely filled with the first portion OC1. The first portion OC1 may be directly in contact with each of the first light shielding pattern LCP1 and the second light shielding pattern LCP2. The first portion OC1 may be disposed on the sensor layer TU. The first portion OC1 may be disposed directly on the sensor layer TU.

FIG. 5 is an enlarged cross-sectional view of an area AA′ of FIG. 4. In FIG. 5, detailed descriptions of elements described with reference to FIGS. 3A to 4 will be omitted.

Referring to FIG. 5, a width d1 in the second direction DR2 of the light control pattern LCP may be greater than a distance d2 in the second direction DR2 between two adjacent light control patterns LCP. The width d1 in the second direction DR2 of the light control pattern LCP may be equal to or greater than about 17 micrometers and equal to or smaller than about 21 micrometers. As an example, the width d1 in the second direction DR2 of the light control pattern LCP may be about 21 micrometers.

If the width d1 of the light control pattern LCP in the second direction DR2 is excessively large, the width of the hole HL in the second direction DR2 becomes excessively small, making it difficult to deposit the first light shielding pattern LSP1 and the second light shielding pattern LSP2 during the manufacturing process of the display module DM. Conversely, if the width d1 of the light control pattern LCP in the second direction DR2 is excessively small, the width of the hole HL in the second direction DR2 becomes excessively large, reducing the ability to absorb the side light L2 (refer to FIG. 4) and diminishing the front luminance rate. The distance d2 between two adjacent light control patterns LCP in the second direction DR2 may be equal to or greater than about 2 micrometers and equal to or smaller than about 4 micrometers. The distance d2 between two adjacent light control patterns LCP in the second direction DR2 may be substantially the same as the width of the hole HL in the second direction DR2.

Each of a width d3 of the first light shielding pattern LSP1 in the second direction DR2 and a width d4 of the second light shielding pattern LSP2 in the second direction DR2 may be smaller than the width d5 of the protrusion pattern PP in the second direction DR2. The width d3 of the first light shielding pattern LSP1 in the second direction DR2 may be substantially the same as or may be different from the width d4 of the second light shielding pattern LSP2 in the second direction DR2. Each of the width d3 of the first light shielding pattern LSP1 in the second direction DR2 and the width d4 of the second light shielding pattern LSP2 in the second direction DR2 may be smaller than about 2 micrometers.

If each of the width d3 of the first light shielding pattern LSP1 in the second direction DR2 and the width d4 of the second light shielding pattern LSP2 in the second direction DR2 is excessively large, the front luminance rate may decrease due to increased absorption of the front light L1 (refer to FIG. 4). The width d5 of the protrusion pattern PP in the second direction DR2 may be a value obtained by subtracting each of the width d3 of the first light shielding pattern LSP1 in the second direction DR2 and the width d4 of the second light shielding pattern LSP2 in the second direction DR2 from the width d1 of the light control pattern LCP in the second direction DR2. Each of the first light shielding pattern LSP1 and the second light shielding pattern LSP2 may have substantially the same height as a height of the protrusion pattern PP.

If the height of each of the first light shielding pattern LSP1 and the second light shielding pattern LSP2 is excessively large compared with the height of the protrusion pattern PP, it becomes challenging to planarize the display module DM (refer to FIG. 4). Conversely, if the height of each of the first light shielding pattern LSP1 and the second light shielding pattern LSP2 is excessively small compared with the height of the protrusion pattern PP, a cross-sectional area of each of the first light shielding pattern LSP1 and the second light shielding pattern LSP2 for absorbing side light L2 (refer to FIG. 4) decreases, making it difficult to improve the front luminance rate.

In a conventional display module, a light shielding pattern of a light control layer has a width equal to or greater than about 4 micrometers, which reduces the front luminance rate. In contrast, the display module DM (refer to FIG. 4) of the present disclosure features the first and second light shielding patterns LSP1 and LSP2 with widths d3 and d4 that are equal to or smaller than about 2 micrometers. Additionally, the first and second light shielding patterns LSP1 and LSP2 may be spaced apart from each other by the distance d2 in the second direction DR2 between two adjacent light control patterns LCP. Therefore, when compared with the conventional display module, a cross-sectional area available for the emission of the front light L1 (refer to FIG. 4) is increased by the distance d2, thereby improving the front luminance rate.

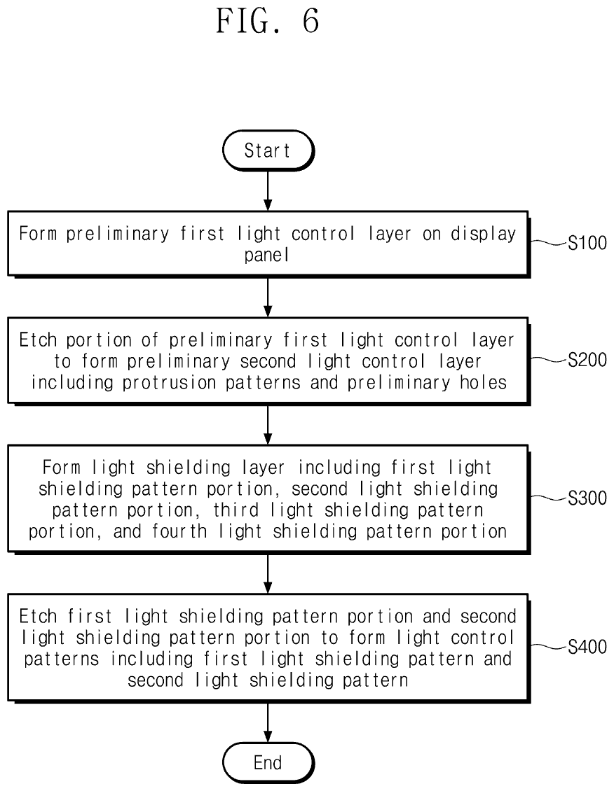

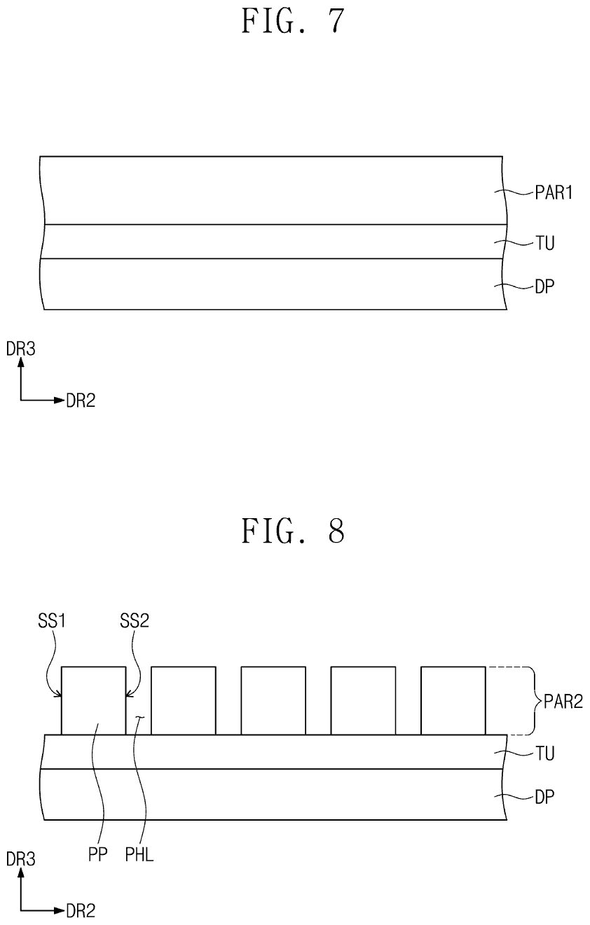

In one embodiment, the display module of the present disclosure may be manufactured using the method described herein. FIG. 6 is a flowchart illustrating the method of manufacturing the display module according to an embodiment of the present disclosure. FIGS. 7 to 12 are cross-sectional views of the method of manufacturing the display module according to an embodiment of the present disclosure.

Referring to FIG. 6, the manufacturing method of the display module may include forming a preliminary first light control layer on the display panel (S100), etching a portion of the preliminary first light control layer to form a preliminary second light control layer including the protrusion patterns and a plurality of preliminary holes (S200), forming a light shielding layer including a first light shielding pattern portion, a second light shielding pattern portion, a third light shielding pattern portion, and a fourth light shielding pattern portion (S300), and etching the first light shielding pattern portion and the second light shielding pattern portion to form the light control patterns including the first light shielding pattern and the second light shielding pattern (S400).

Referring to FIG. 7, the preliminary first light control layer PAR1 may be disposed on the display panel DP during the formation of the preliminary first light control layer PAR1. The preliminary first light control layer PAR1 may be disposed on the sensor layer TU. The preliminary first light control layer PAR1 may be formed by various methods, such as a vacuum deposition method, a spin coating method, a cast method, an LB (Langmuir-Blodgett) method, an inkjet printing method, a laser printing method, an LITI (Laser Induced Thermal Imaging) method, etc. As an example, the preliminary first light control layer PAR1 may be formed by inkjet printing. The preliminary first light control layer PAR1 may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin. As an example, the preliminary first light control layer PAR1 may include the acrylic-based resin.

Referring to FIG. 8, in the forming of the preliminary second light control layer PAR2, preliminary holes PHL may be formed by a dry etching method or a wet etching method. The preliminary second light control layer PAR2 may include the protrusion patterns PP and the preliminary holes PHL. Each preliminary hole PHL refers to the space between two adjacent protrusion patterns PP. Each preliminary hole PHL may completely penetrate through the preliminary second light control layer PAR2. The first side surface SS1 of one protrusion pattern PP and the second side surface SS2 of another protrusion pattern PP adjacent to the one protrusion pattern PP may define the preliminary hole PHL.

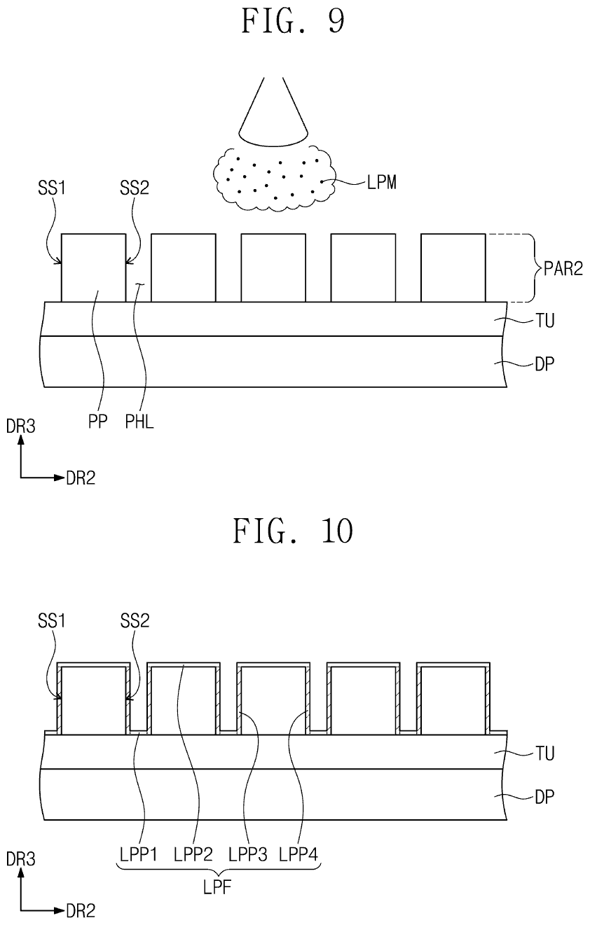

Referring to FIGS. 9 and 10, the forming of the light shielding layer LPF may include depositing a light shielding material LPM containing at least one of amorphous carbon and silicon carbide on the display panel DP using a chemical vapor deposition (CVD) method. The light shielding layer LPF may include the first light shielding pattern portion LPP1 overlapping each of the preliminary holes PHL when viewed in the plane, the second light shielding pattern portion LPP2 disposed on the protrusion patterns PP, the third light shielding pattern portion LPP3 disposed on the first side surface SS1, and the fourth light shielding pattern portion LPP4 disposed on the second side surface SS2. The third light shielding pattern portion LPP3 and the fourth light shielding pattern portion LPP4 may correspond to the first light shielding pattern LSP1 and the second light shielding pattern LSP2 described with reference to FIG. 4, respectively. The light shielding material LPM may be coated on the preliminary second light control layer PAR2 to form the light shielding layer LPF.

Since the light shielding layer LPF is formed through the chemical vapor deposition method rather than a sputter deposition method, the light shielding layer LPF may have a uniform thickness, and thus, the yield of the light shielding layer LPF may be improved. When the sputter deposition method is used to form the light shielding layer LPF, a thickness of the third light shielding pattern portion LPP3 or a thickness of the fourth light shielding pattern portion LPP4 may be smaller than a thickness of the first light shielding pattern portion LPP1 or a thickness of the second light shielding pattern portion LPP2. Additionally, the thickness of the third light shielding pattern portion LPP3 and the fourth light shielding pattern portion LPP4 may be non-uniform, making it challenging to improve the front luminance rate.

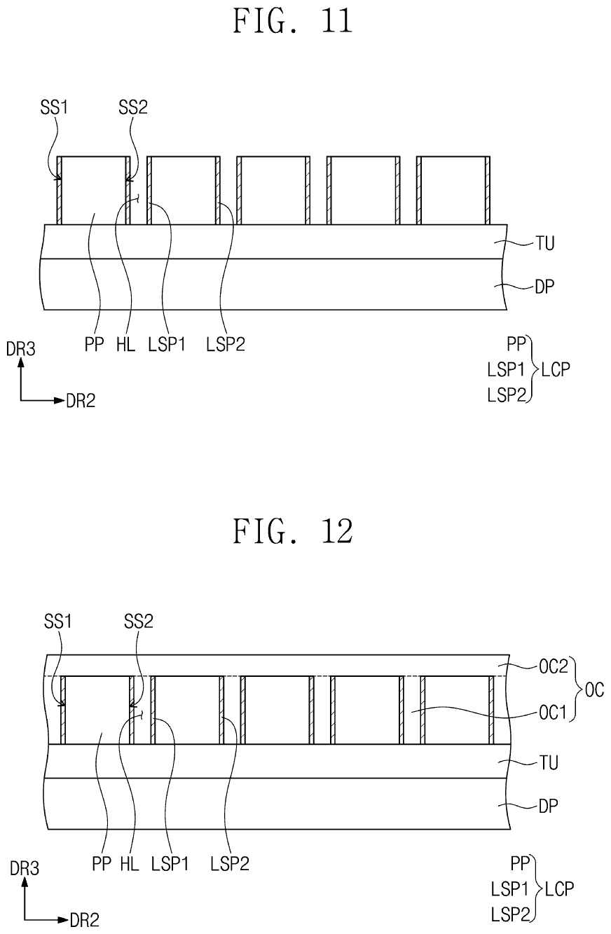

Referring to FIGS. 10 and 11, the first light shielding pattern portion LPP1 and the second light shielding pattern portion LPP2 may be removed through an anisotropic dry etching process in the forming of the light control patterns LCP. When the first light shielding pattern portion LPP1 and the second light shielding pattern portion LPP2 are removed through the anisotropic dry etching process, the first light shielding pattern LSP1 and the second light shielding pattern LSP2 may be formed without reducing the thickness of the third light shielding pattern portion LPP3 and the fourth light shielding pattern portion LPP4.

Referring to FIG. 12, the manufacturing method of the display module may further include forming the coating layer OC. The coating layer OC may be formed by various methods, such as a vacuum deposition method, a spin coating method, a cast method, an LB (Langmuir-Blodgett) method, an inkjet printing method, a laser printing method, an LITI (Laser Induced Thermal Imaging) method, etc. As an example, the coating layer OC may be formed by inkjet printing. The first portion OC1 and the second portion OC2 may be sequentially formed through continuous inkjet printing methods.

Hereinafter, a transmittance of the first light shielding pattern included in the light control layer of the display module according to the present disclosure will be described in detail. Optical properties of the first light shielding pattern described hereinafter may be applied to the second light shielding pattern. In addition, embodiments shown below are examples to aid understanding of the present disclosure, and the scope of the present disclosure should not be limited thereto or thereby.

Table 1 below shows the wavelength of the light, a thickness of the first light shielding pattern, and the transmittance of the light according to the components of the first light shielding pattern. As the transmittance of the light passing through the first light shielding pattern decreases, the first light shielding pattern may have excellent light absorption ability, and thus, the privacy protection of the display module may be improved.

TABLE 1

| | | Wavelength of | Thickness | Transmittance |
|---|---|---|---|---|
| | components | light (nm) | (angstrom) | (%) |
| embodiment | amorphous | 400 | 1500 | 37 |
| example 1 | carbon | | | |
| embodiment | amorphous | 400 | 2500 | 18.1 |
| example 2 | carbon | | | |
| embodiment | amorphous | 300 | 1500 | 14.9 |
| example 3 | carbon | | | |
| embodiment | amorphous | 300 | 2500 | 3.8 |
| example 4 | carbon | | | |
| embodiment | silicon | 400 | 1500 | 46.3 |
| example 5 | carbide | | | |
| embodiment | silicon | 400 | 2500 | 28.3 |
| example 6 | carbide | | | |
| embodiment | silicon | 300 | 1500 | 4.7 |
| example 7 | carbide | | | |
| embodiment | silicon | 300 | 2500 | 1.1 |
| example 8 | carbide | | | |
| embodiment | silicon | 400 | 1500 | 52.2 |
| example 9 | carbide | | | |
| embodiment | silicon | 400 | 2500 | 34.4 |
| example 10 | carbide | | | |
| embodiment | silicon | 300 | 1500 | 6.9 |
| example 11 | carbide | | | |
| embodiment | silicon | 300 | 2500 | 1.1 |
| example 12 | carbide | | | |

Referring to Table 1, embodiment example 1 to embodiment example 12 show the transmittance equal to or greater than about 1.1% and equal to or smaller than about 52.2% with respect to the light having the wavelength of about 300 nm and about 400 nm, and when the thickness of the first light shielding pattern is large, the transmittance is reduced. As shown in the embodiment example 1 to embodiment example 12, the first light shielding pattern absorbs between about 47.8% and about 98.9% of the light. Consequently, at least about 47.8% and up to about 98.9% of the side light generated within the display panel is absorbed, thereby improving the privacy protection of the display module. Since the display module of the present disclosure includes the first light shielding pattern and the second light shielding pattern, each of which includes at least one of amorphous carbon and silicon carbide having the high extinction coefficient (k) compared with the conventional light absorbing material, an absorption rate of the side light may increase, and privacy protection issues related to information being exposed to others may be improved.

Since the display module of the present disclosure features light shielding patterns that are thinner and spaced apart compared to those in conventional display modules, the cross-sectional area for front light emission is increased, thereby enhancing the front luminance rate.

In the manufacturing method of this display module, since the first light shielding pattern and the second light shielding pattern are formed through chemical vapor deposition, the yield of the display module may be improved compared to conventional manufacturing processes that rely on sputter deposition.

Although the embodiments of the present disclosure have been described, it is understood that the present disclosure should not be limited to these embodiments but various changes and modifications can be made by those of ordinary skill in the art within the spirit and scope of the present disclosure as hereinafter claimed.

Therefore, the disclosed subject matter should not be limited to any single embodiment described herein.

What is claimed is:

1. A display module comprising:
a display panel; and
a light control layer disposed on the display panel, the light control layer comprising a plurality of light control patterns extending in a first direction and spaced apart from each other in a second direction intersecting the first direction, each of the light control patterns comprising:
a protrusion pattern extending in the first direction and comprising a first side surface and a second side surface opposite to the first side surface in the second direction;
a first light shielding pattern disposed on the first side surface; and
a second light shielding pattern disposed on the second side surface, wherein each of the first light shielding pattern and the second light shielding pattern comprises amorphous carbon or silicon carbide.

2. The display module of claim 1, wherein each of the first light shielding pattern and the second light shielding pattern has an extinction coefficient greater than an extinction coefficient of the protrusion pattern.

3. The display module of claim 2, wherein the extinction coefficient of each of the first light shielding pattern and the second light shielding pattern is equal to or greater than about 0.32 and equal to or smaller than about 0.43.

4. The display module of claim 1, wherein the light control layer further comprises a coating layer disposed on the light control patterns.

5. The display module of claim 4, wherein each of the protrusion pattern and the coating layer comprises an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

6. The display module of claim 4, wherein the light control layer includes a hole between two adjacent light control patterns, and the coating layer comprises:
a first portion in the hole; and
a second portion disposed on the first portion and the plurality of light control patterns.

7. The display module of claim 6, wherein the first portion is directly in contact with each of the first light shielding pattern and the second light shielding pattern.

8. The display module of claim 1, wherein the first light shielding pattern is directly disposed on the first side surface, and the second light shielding pattern is directly disposed on the second side surface.

9. The display module of claim 1, wherein a width of each of the light control patterns in the second direction is greater than a distance between two adjacent light control patterns in the second direction.

10. The display module of claim 1, wherein a width of each of the first light shielding pattern and the second light shielding pattern in the second direction is smaller than a width of the protrusion pattern in the second direction.

11. The display module of claim 10, wherein the width of each of the first light shielding pattern and the second light shielding pattern is equal to or smaller than about 2 micrometers.

12. The display module of claim 1, wherein a height of each of the first light shielding pattern and the second light shielding pattern is substantially the same as a height of the protrusion pattern.

13. The display module of claim 1, wherein the display panel comprises a plurality of light emitting elements, and each of the plurality of light emitting elements overlaps two or more of the light control patterns when viewed in a plane.

14. A method of manufacturing a display module, comprising:
forming a preliminary first light control layer on a display panel;
etching the preliminary first light control layer to form a preliminary second light control layer comprising a plurality of protrusion patterns extending in a first direction and comprising a first side surface and a second side surface opposite to the first side surface in a second direction intersecting the first direction and a plurality of preliminary holes between two adjacent protrusion patterns;
forming a light shielding layer comprising a first light shielding pattern portion overlapping each of the plurality of preliminary holes, a second light shielding pattern portion disposed on the plurality of protrusion patterns, a third light shielding pattern portion disposed on the first side surface, and a fourth light shielding pattern portion disposed on the second side surface; and
etching the first and second light shielding pattern portions to form a plurality of light control patterns comprising one of the protrusion patterns, a first light shielding pattern disposed on the first side surface, and a second light shielding pattern disposed on the second side surface, wherein the first light shielding patterns and the second light shielding patterns comprise amorphous carbon or silicon carbide.

15. The method of claim 14, further comprising forming a coating layer comprising a first portion filled in a hole between two adjacent light control patterns and a second portion disposed on the first portion, the first light shielding patterns, the second light shielding patterns, and the protrusion patterns.

16. The method of claim 14, wherein the forming of the light shielding layer comprises depositing a light shielding material comprising amorphous carbon or silicon carbide on the display panel through chemical vapor deposition.

17. The method of claim 14, wherein the preliminary first light control layer is formed through inkjet printing.

18. The method of claim 14, wherein the first light shielding pattern portion and the second light shielding pattern portion are removed through an anisotropic dry etching process in the forming of the first light shielding pattern and the second light shielding pattern.

19. The method of claim 14, wherein each of the first light shielding pattern and the second light shielding pattern has an extinction coefficient equal to or greater than about 0.32 and equal to or smaller than about 0.43.

20. The method of claim 14, wherein each of the plurality of preliminary holes completely penetrates through the preliminary second light control layer.

21. An electronic apparatus comprising:
a display module comprising:
a display panel; and
a light control layer disposed on the display panel, the light control layer comprising a plurality of light control patterns extending in a first direction and spaced apart from each other in a second direction intersecting the first direction, each of the light control patterns comprising:
a protrusion pattern extending in the first direction and comprising a first side surface and a second side surface opposite to the first side surface in the second direction;
a first light shielding pattern disposed on the first side surface; and
a second light shielding pattern disposed on the second side surface, wherein each of the first light shielding pattern and the second light shielding pattern comprises amorphous carbon or silicon carbide.
